(19) United States
(12) Patent Application Publication
(10) Pub. No.: US 2025/0239892 A1
(43) Pub. Date: Jul. 24, 2025

(54) MAGNETIC FIELD SHIELDING MODULE FOR ELECTRIC VEHICLE, AND WIRELESS POWER TRANSMISSION MODULE FOR ELECTRIC VEHICLE INCLUDING SAME

(71) Applicant: AMOSENSE CO.,LTD, Cheonan-si, Chungcheongnam-do (KR)

(72) Inventor: Kil Jae JANG, Cheonan-si, Chungcheongnam-do (KR)

(21) Appl. No.: 18/705,470

(22) PCT Filed: Oct. 14, 2022
(86) PCT No.: PCT/KR2022/015652

§ 371 Date: Apr. 26, 2024

(30) Foreign Application Priority Data
Oct. 27, 2021 (KR) 10-2021-0144588

(51) Int. Cl. H02J 50/70; B60L 53/122; H01F 27/36; H02J 50/00; H02J 50/10

(52) U.S. Cl. CPC H02J 50/70; B60L 53/122; H02J 50/005; H02J 50/10; H01F 27/36

(57) ABSTRACT

Provided is a magnetic field shielding module for an electric vehicle. The magnetic field shielding module for an electric vehicle according to an embodiment of the present invention is utilized in a wireless power transmission module for an electric vehicle, and comprises: a shielding layer including a plurality of unit blocks which are made of ferrite materials so as to be able to block a magnetic field generated from a flat coil in which a conductive member is wound multiple times; and a coil accommodation groove recessed to a certain depth from one surface of the shielding layer so as to be able to accommodate the thickness of the flat coil. The shielding layer is formed in a plate shape having a certain area by arranging the plurality of unit blocks adjacent to each other.

### TECHNICAL FIELD

The present disclosure relates to a magnetic field shielding module for an electric vehicle and a wireless power transfer module for an electric vehicle including the same.

### BACKGROUND ART

Electric vehicles currently under development are using wireless charging technology to overcome limitations of batteries.

Such wireless charging is performed through a wireless power transfer module including a coil that wirelessly transmits or receives power supplied from the outside and a shielding sheet disposed on one surface of the coil to shield a magnetic field generated from the coil.

In this case, the shielding sheet used in the wireless power transfer module for vehicles is generally a magnetic sheet made of a ferrite material. However, the wireless power transfer module for vehicles such as electric vehicles has a large handling power and transfer distance compared to the wireless power transfer module for mobile, so the shielding sheet applied to the wireless power transfer module for vehicles is configured to have a large-area of 100 mm×100 mm or more while having a thickness of approximately 5 mm.

Accordingly, the conventional vehicle shielding sheet made of the ferrite material may satisfy the required power transmission efficiency, but has the disadvantage of having a large overall weight.

Accordingly, when the shielding sheet for vehicles is applied to electric vehicles, the batteries of electric vehicles can be easily charged using wireless power, but the electric vehicles have a problem in that the overall weight of the wireless power transfer module increases due to the weight of the shielding sheet, so the fuel efficiency is lowered.

### DISCLOSURE

### Technical Problem

The present disclosure has been devised in consideration of the above points, and it is an object of the present disclosure to provide a magnetic field shielding module for an electric vehicle which can reduce the overall weight while satisfying the required power transmission efficiency even if the shielding module for shielding a magnetic field is implemented in a large-area, and a wireless power transfer module for an electric vehicle including the same.

Further, another object of the present disclosure is to provide a magnetic field shielding module for an electric vehicle which can enhance the mass production rate while the shielding module for shielding a magnetic field is implemented in a large-area, and a wireless power transfer module for an electric vehicle including the same.

### Technical Solution

In order to solve the above-mentioned problems, the present disclosure provides a magnetic field shielding module for an electric vehicle, wherein the magnetic field shielding module is applied to a wireless power transfer module, the magnetic field shielding module may include: a shielding layer including a plurality of unit blocks made of a ferrite material to shield a magnetic field generated from a planar coil in which a conductive member is wound multiple times; and a coil accommodating groove formed to be recessed at a predetermined depth from one surface of the shielding layer to receive the thickness of the planar coil, and wherein the shielding layer may be formed in a plate shape having a predetermined area by the plurality of unit blocks arranged adjacent to each other, and wherein at least some unit blocks among the plurality of unit blocks may include a unit accommodating groove for receiving a part of the planar coil, and wherein the unit accommodating grooves formed in each of the at least some of the unit blocks may be connected to each other in a state in which the plurality of unit blocks are arranged to be adjacent to each other to form the coil accommodating groove having a shape corresponding to the planar coil.

Meanwhile, the present disclosure provides a wireless power transfer antenna for electric vehicles including: a wireless power transfer antenna formed of a planar coil in which a conductive member is wound multiple times; and a magnetic field shielding module made of a magnetic material to shield a magnetic field generated from the planar coil, wherein the magnetic field shielding module may include: a shielding layer including a plurality of unit blocks made of a ferrite material; and a coil accommodating groove formed to be recessed at a predetermined depth from one surface of the shielding layer to receive the thickness of the planar coil, and wherein the shielding layer may be formed in a plate shape having a predetermined area by the plurality of unit blocks arranged adjacent to each other, and wherein at least some unit blocks among the plurality of unit blocks may include a unit accommodating groove for receiving a part of the planar coil, and wherein the unit accommodating grooves formed in each of the at least some of the unit blocks may be connected to each other in a state in which the plurality of unit blocks are arranged to be adjacent to each other to form the coil accommodating groove having a shape corresponding to the planar coil.

In addition, the plurality of unit blocks may include a first unit block having a curved unit accommodating groove, a second unit block having a straight unit accommodating groove, and a third unit block having no unit accommodating groove.

In addition, the coil accommodating groove may be formed to be recessed from one surface of the shielding layer to have a depth equal to or greater than a wire diameter of the conductive member.

In addition, the magnetic field shielding module may further include: an auxiliary blocking member made of a magnetic material and disposed in the coil accommodating groove, wherein the auxiliary blocking member may include: a plate-shaped support plate, a partition member extending from the support plate to a predetermined height and formed in a spiral shape, and a seating groove defined by the support plate and the partition member, and wherein the partition member may be disposed to be positioned between turns adjacent to each other in the planar coil.

In addition, the coil accommodating groove may be formed as an accommodating groove having both sides thereof sealed.

### Advantageous Effects

According to the present disclosure, even if the magnetic field shielding module is implemented in a large-area through a plurality of unit blocks arranged to be adjacent to each other, it is possible to satisfy the required power transmission efficiency and to reduce the weight.

In addition, according to the present disclosure, it is possible to enhance the mass production rate even if the magnetic field shielding module is configured in a large-area.

### DESCRIPTION OF DRAWINGS

FIG. 1 is a view illustrating a wireless power transfer module for an electric vehicle according to an embodiment of the present disclosure.

FIG. 2 is an exploded view of FIG. 1.

FIG. 3 is a cross-sectional view taken along line A-A of FIG. 1.

FIG. 4 is a view illustrating a wireless power transfer module for an electric vehicle according to another embodiment of the present disclosure.

FIG. 5 is an exploded view of FIG. 4.

FIG. 6 is a cross-sectional view taken along line B-B of FIG. 4.

FIG. 7 is a view illustrating the separation of a plurality of unit blocks constituting the shielding layer in a magnetic field shielding module for an electric vehicle applied in FIG. 1 and FIG. 4.

FIG. 8 is a view illustrating a state in which the wireless power transfer module for an electric vehicle according to an embodiment of the present disclosure is accommodated in a case.

### MODES OF THE INVENTION

Hereinafter, embodiments of the present disclosure will be described in detail with reference to the accompanying drawings so that those skilled in the art can easily implement them. The present disclosure may be implemented in various different forms and is not limited to the embodiments described herein. In the drawings, in order to clearly explain the present disclosure, parts irrelevant to the description were omitted, and the same or similar components will be denoted by the same reference numerals throughout the entire specification.

Magnetic field shielding modules 110 and 210 for an electric vehicle according to an embodiment of the present disclosure may be applied to wireless power transfer modules 100 and 200 for the electric vehicle, and the wireless power transfer modules 100 and 200 for the electric vehicle may charge a battery of the electric vehicle.

Such magnetic field shielding modules 110 and 210 for the electric vehicle may be implemented with a large-area where at least one of a total width, a total length, and a diameter is 100 mm or more. For example, the magnetic field shielding modules 110 and 210 for the electric vehicle may have the total width and the total length of 100 mm or more, respectively, and may be implemented with a size of 400 mm×400 mm.

However, the total size of the magnetic field shielding modules 110 and 210 for the electric vehicle is not limited thereto, and when the size is 100 mm×100 mm or more or the diameter is 100 mm or more, they may be changed to various sizes according to design conditions.

In addition, the magnetic field shielding modules 110 and 210 for the electric vehicle according to an embodiment of the present disclosure may be applied to wireless power transmission modules for the electric vehicle to transmit wireless power to wireless power reception modules installed in the electric vehicle, or may be applied to the wireless power reception modules for the electric vehicle installed in the electric vehicle to receive wireless power transmitted from the wireless power transmission modules for the electric vehicle.

In this case, even if the magnetic field shielding modules 110 and 210 for the electric vehicle according to an embodiment of the present disclosure may be implemented in a large-area of 100 mm×100 mm or more, the magnetic field shielding modules 110 and 210 for the electric vehicle according to an embodiment of the present disclosure may satisfy the required power transmission efficiency and reduce the total weight, and increase the mass productivity while being implemented in a large-area.

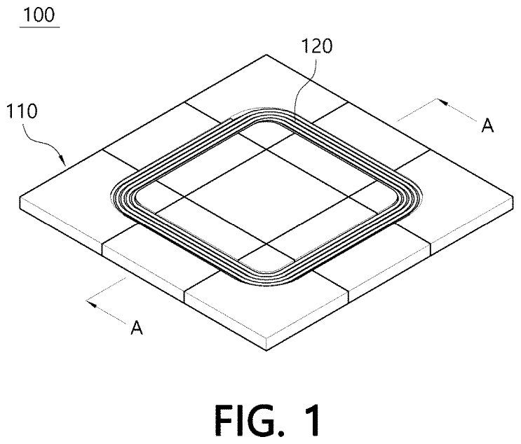

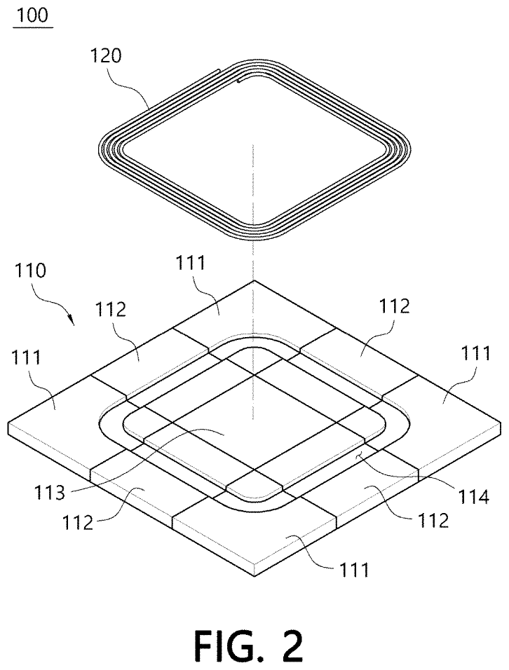

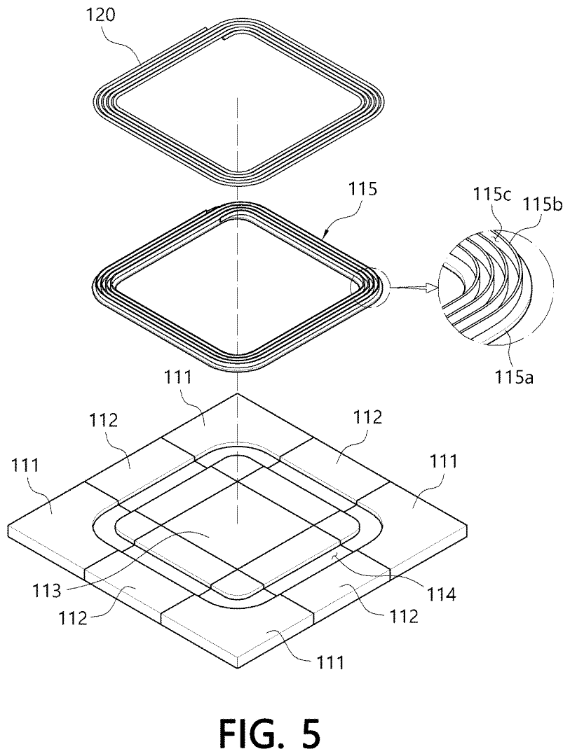

To this end, the magnetic field shielding modules 110 and 210 for the electric vehicle according to an embodiment of the present disclosure may include a shielding layer and a coil accommodating groove 114 as illustrated in FIGS. 1 to 7.

That is, the magnetic field shielding modules 110 and 210 for the electric vehicle according to an embodiment of the present disclosure may include a shielding layer for shielding a magnetic field generated from a planar coil 120, and a coil accommodating groove 114 for receiving the planar coil 120, and the coil accommodating groove 114 may be a accommodating groove formed to be recessed at a predetermined depth from one surface of the shielding layer.

Specifically, the shielding layer may include a plurality of unit blocks 111, 112, and 113 made of ferrite material to shield a magnetic field generated from the planar coil 120, and the plurality of unit blocks 111, 112, and 113 may be arranged such that one side thereof is adjacent to each other.

In the present disclosure, each of the unit blocks 111, 112, and 113 may be sintered through a firing process after pressurizing a ferrite powder, and each of the unit blocks 111, 112, and 113 may be made of Ni—Zn ferrite or Mn—Zn ferrite, but may be made of Mn—Zn ferrite to exhibit relatively excellent performance in a frequency band of 100 to 350 kHz.

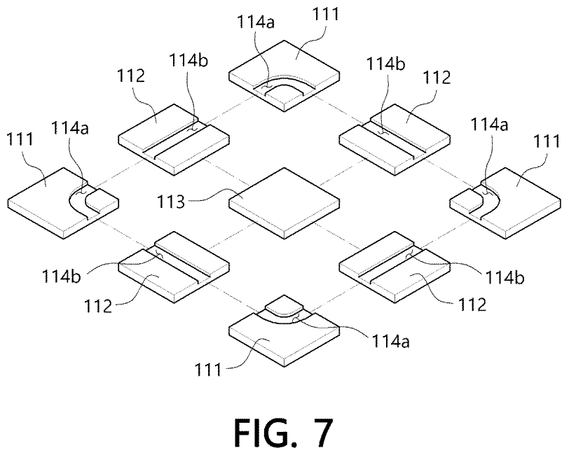

A plurality of such unit blocks 111, 112, and 113 may be provided, separated from each other, as illustrated in FIG. 7, and the plurality of unit blocks 111, 112, and 113 may be arranged such that one side thereof is adjacent to each other to form a plate-shaped shielding layer having a predetermined area.

Accordingly, in the magnetic field shielding modules 110 and 210 for the electric vehicle according to an embodiment of the present disclosure, the shielding layer may be implemented in a large-area having a size of 100 mm×100 mm or more or a diameter of 100 mm or more by appropriately arranging the plurality of unit blocks 111, 112, and 113.

Herein, the plurality of unit blocks 111, 112, and 113 may be arranged in a matrix structure of m×n (m, n are natural numbers, respectively), and may have the same size or different sizes.

In this case, in the magnetic field shielding modules 110 and 210 for the electric vehicle according to an embodiment of the present disclosure, at least some the unit blocks 111, and 112 among the plurality of unit blocks 111, 112, and 113 may include unit accommodating grooves 114a, and 114b for receiving a prat of the planar coil 120.

In addition, the unit accommodating grooves 114a, and 114b formed in each of the at least some of the unit blocks 111, and 112 may be connected to each other to form the coil accommodating groove 114 having a shape corresponding to the planar coil 120.

For example, as illustrated in FIG. 7, the plurality of unit blocks 111, 112, and 113 may include a first unit block 111 having a curved unit accommodating groove 114a formed on one surface thereof, a second unit block 112 having a straight unit accommodating groove 114b formed on one surface thereof, and a third unit block 113 having no unit accommodating grooves 114a, and 114b.

Accordingly, when the first unit block 111, the second unit block 112, and the third unit block 113 are appropriately combined and arranged such that one side thereof is adjacent to each other, the shielding layer may be implemented in a large-area having a size of 100 mm×100 mm or more or a diameter of 100 mm or more, and the coil accommodating groove 114 may have a shape corresponding to the flat plate-shaped coil 200 by being connected the curved unit accommodating groove 114a formed in the first unit block and the straight unit accommodating groove 114b formed in the second unit block 112.

Accordingly, when the first unit block 111, the second unit block 112, and the third unit block 113 are appropriately combined, the magnetic field shielding modules 110 and 210 for the electric vehicle according to an embodiment of the present disclosure may have a large-area having a size of 100 mm×100 mm or more or a diameter of 100 mm or more, and may constitute the shielding layer having the coil accommodating groove 114 formed on one surface thereof for accommodating the flat plate-shaped coil 200.

However, the unit blocks 111, 112, and 113 for constituting the shielding layer are not limited to the above-described first unit block 111, the second unit block 112, and the third unit block 113, and the shape of the unit accommodating grooves 114a, and 114b of the first unit block 111 and the second unit block 112 for constituting the shielding layer may be appropriately changed depending on the size or shape of the flat plate-shaped coil 200, and at least any one of the first unit block 111, the second unit 112, and the third unit 113 may not be used to constitute the shielding layer according to the size or shape of the planar coil 120.

In this case, at least one of the first unit block 111, second unit block 112, and third unit block 113 may be provided in plural numbers.

For example, when the shielding layer is composed of nine unit blocks 111, 112, and 113, four first unit blocks 111 and four second unit blocks 112 may be used, and one third unit block 113 may be used.

In this case, when four first unit blocks 111 and four second unit blocks 112 and one third unit block 113 are connected to each other, the magnetic field shielding modules 110 and 210 for the electric vehicle according to an embodiment of the present disclosure may constitute the shielding layer having a coil accommodating groove 114 formed in a closed loop shape of approximately a quadrangle on one surface.

Accordingly, the magnetic field shielding modules 110 and 210 for electric vehicles according to an embodiment of the present disclosure may minimize the types of unit blocks 111, 112, and 113 used to constitute the shielding layer, thereby minimizing the number of molds for producing the unit blocks 111, 112, and 113.

Through this, even if the shielding layer is composed of the plurality of unit blocks 111, 112, and 113 and includes the coil accommodating groove 114 corresponding to the planar coil 120 on one surface of the shielding layer composed of the plurality of unit blocks 111, 112, and 113, the magnetic field shielding modules 110 and 210 for the electric vehicle according to an embodiment of the present disclosure may constitute the shielding layer including the coil accommodating groove 114 using a minimum mold, thereby minimizing the increase in production costs and maintaining the mass productivity.

In addition, the magnetic field shielding modules 110 and 210 for the electric vehicle according to an embodiment of the present disclosure may increase productivity and mass production by simply increasing the size of the coil accommodating groove 114 and the total area of the shielding layer by appropriately combining the above-described unit blocks 111, 112, and 113.

However, the total number of unit blocks 111, 112, and 113 for constituting the shielding layer is not limited thereto, and the total number of unit blocks 111, 112, and 113 may be appropriately changed according to the total area of the shielding layer.

In this case, the unit accommodating grooves 114a, and 114b for forming the coil accommodating groove 114 may be accommodating grooves formed into a predetermined depth from one surface of the unit blocks 111, and 112 so that both sides thereof are sealed. In addition, the unit accommodating grooves 114a, and 114b may be formed to have a depth that is the same as the wire diameter or thickness of the conductive member constituting the planar coil 120 or has a depth larger than the wire diameter or thickness of the conductive member.

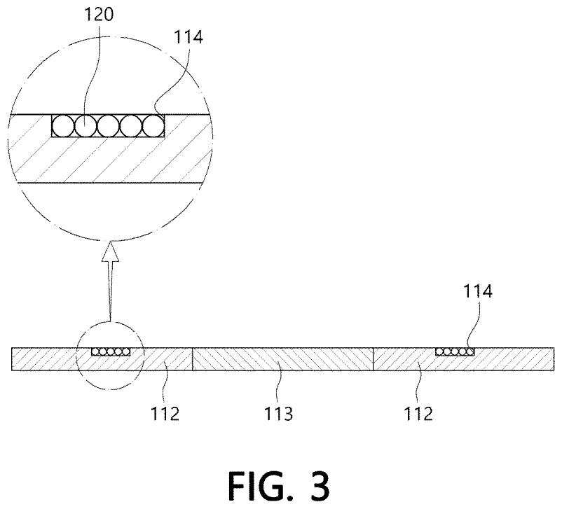

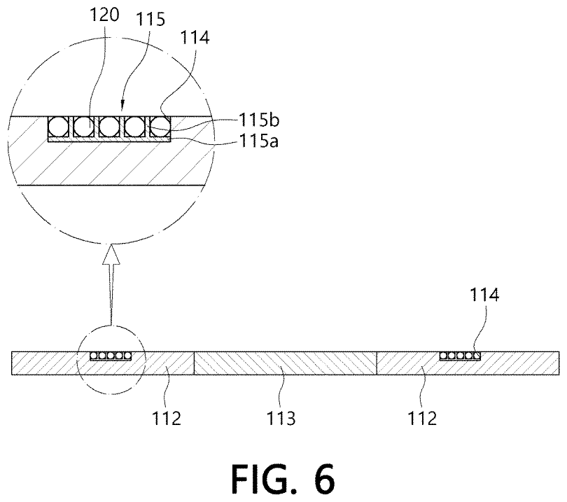

Accordingly, when the planar coil 120 is inserted into the coil accommodating groove 114 formed by being connected the unit accommodating grooves 114a, and 114b, the planar coil 200 may be disposed in the coil accommodating groove 114 so as not to protrude outward from one surface of the shielding layer as illustrated in FIGS. 3 and 6.

That is, when the planar coil 120 is inserted into the coil accommodating groove 114, the planar coil 120 may be surrounded by the bottom surface and both sides of the coil accommodating groove 114.

For this reason, in the magnetic field shielding modules 110 and 210 for the electric vehicle according to an embodiment of the present disclosure, the planar coil 120 inserted into the coil accommodating groove 114 may improve the concentration of the magnetic field, thereby improving wireless power transmission efficiency.

Accordingly, the magnetic field shielding modules 110 and 210 for the electric vehicle according to an embodiment of the present disclosure may realize wireless power transmission efficiency equal to or more than a conventional level even if the thickness of the shielding layer is thinner than the conventional level, thereby reducing the total weight as much as corresponding to the thinned thickness.

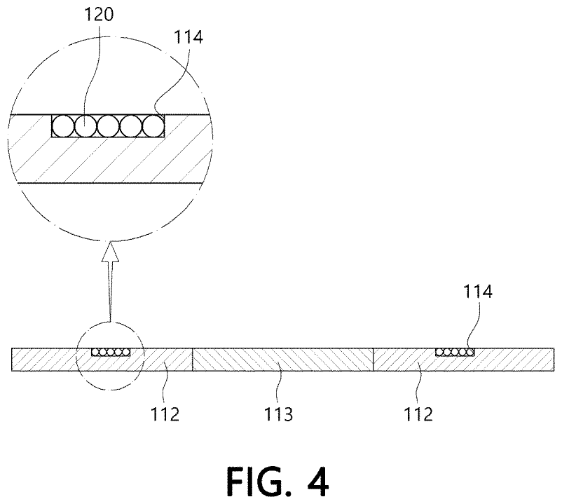

Meanwhile, the magnetic field shielding module 210 for the electric vehicle according to an embodiment of the present disclosure may further include an auxiliary blocking member 115 disposed in the coil accommodating groove 114 as shown in FIGS. 4 to 6.

The auxiliary blocking member 115 may be made of a magnetic material to shield the magnetic field generated by the planar coil 120.

Through this, the auxiliary blocking member 115 may further increase the power transmission efficiency of the planar coil 120 by preventing leakage of a magnetic field generated from the planar coil 120.

In this case, the auxiliary blocking member 115 may be disposed so that a portion of the auxiliary blocking member 115 is positioned between turns adjacent to each other in the planar coil 120 inserted into the coil accommodating groove 114.

To this end, the auxiliary blocking member 115 may include a plate-shaped support plate 115a, a partition member 115b extending from the support plate 115a to a predetermined height and formed in a spiral shape, and a seating groove 115c formed by the support plate 115a and the partition member 115b.

Accordingly, the seating grooves 115c partitioned from each other by the partition members 115b along the width direction of the coil accommodating groove 114 may be arranged in a row, and the plurality of seating grooves 115c may be formed in a spiral shape connected to one like the partition members 115b.

Through this, the conductive member forming a coil body in the planar coil 120 may be inserted along the seating groove 115c, and the conductive member inserted along the seating groove 115c may form the coil body in a form that is wound multiple times in one direction.

Accordingly, the partition member 115b may be disposed to be positioned between turns adjacent to each other in the planar coil 120, and the conductive member inserted into the seating groove 115c may be surrounded on both sides by the partition members 115b or by the side surfaces of the partition member 115b and the coil accommodating groove 114.

Through this, the magnetic field shielding module 210 for the electric vehicle according to an embodiment of the present disclosure may more effectively prevent the magnetic field generated from the planar coil 120 from being leaked.

Herein, the auxiliary blocking member 115 may be made of a polymer material such as sandust to easily form the partition member 115b in a spiral shape, although all known magnetic materials used for shielding a magnetic field may be used.

Meanwhile, the above-described magnetic field shielding modules 110 and 210 for the electric vehicle may be implemented as wireless power transfer modules 100 and 200 for the electric vehicle to charge the battery of the electric vehicle.

As an example, the wireless power transfer modules 100 and 200 for the electric vehicle may include at least one wireless power transfer antenna for receiving or transmitting wireless power using a magnetic field of a predetermined frequency band, and magnetic field shielding modules 110 and 210 for shielding a magnetic field generated from the wireless power transfer antenna, as shown in FIGS. 1 to 6, and the magnetic field shielding module may be the magnetic field shielding modules 110 and 210 for the electric vehicle described above.

Herein, the wireless power transfer antenna may be a planar coil 120 in which the conductive member is wound multiple times, and the planar coil 120 may be inserted into a coil accommodating groove 114 formed on one surface of the magnetic field shielding modules 110 and 210 for the electric vehicle.

Since the magnetic field shielding modules 110 and 210 for the electric vehicle are the same as those described above, detailed descriptions will be omitted.

In addition, when the planar coil 120 transmits wireless power to the outside, the wireless power transfer modules 100 and 200 for the electric vehicle may serve as wireless power transmission modules, and when the planar coil 120 receives wireless power, the wireless power transfer modules 100 and 200 for the electric vehicle may serve as wireless power reception modules.

That is, the wireless power transfer modules 100 and 200 for the electric vehicle may be implemented as wireless power transmission modules or wireless power reception modules according to the role of the planar coil 120.

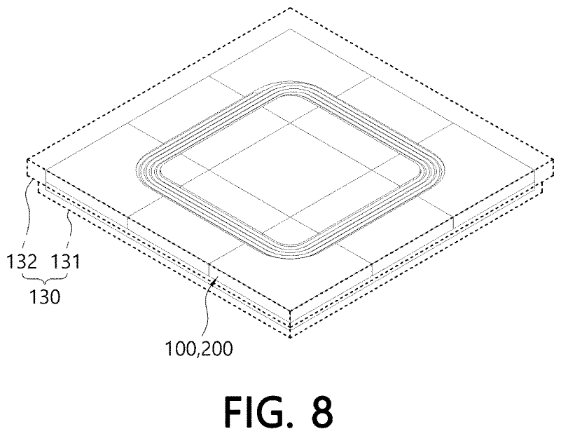

In addition, the above-described wireless power transfer modules 100 and 200 for the electric vehicle may further include a separate case 130 for accommodating the planar coil 120 and the magnetic field shielding modules 110 and 210 as illustrated in FIG. 8.

For example, the case 130 may include a box-shaped main body 131 having an inner space to accommodate the planar coil 120 and the magnetic field shielding modules 110 and 210 therein, and a cover 132 covering an opened upper portion of the main body 131.

Although the spirit of the present disclosure has been described above, the present disclosure is not limited to the embodiments presented in this specification, and those skilled in the art who understand the spirit of the present disclosure may easily propose other embodiments by adding, changing, deleting, and adding components within the same spirit, but this is also within the scope of the spirit of the present disclosure.

1. A magnetic field shielding module for an electric vehicle, wherein the magnetic field shielding module is applied to a wireless power transfer module for an electric vehicle, and
the magnetic field shielding module comprising:
a shielding layer including a plurality of unit blocks made of a ferrite material to shield a magnetic field generated from a planar coil in which a conductive member is wound multiple times; and
a coil accommodating groove formed to be recessed at a predetermined depth from one surface of the shielding layer to receive the thickness of the planar coil, wherein the shielding layer is formed in a plate shape having a predetermined area by the plurality of unit blocks arranged adjacent to each other,
wherein at least some unit blocks among the plurality of unit blocks comprise a unit accommodating groove for receiving a part of the planar coil, and
wherein the unit accommodating grooves formed in each of the at least some of the unit blocks are connected to each other in a state in which the plurality of unit blocks are arranged to be adjacent to each other to form the coil accommodating groove having a shape corresponding to the planar coil.

2. The magnetic field shielding module for the electric vehicle of claim 1, wherein the plurality of unit blocks comprise:
a first unit block having a curved unit accommodating groove,
a second unit block having a straight unit accommodating groove, and
a third unit block having no unit accommodating groove.

3. The magnetic field shielding module for the electric vehicle of claim 1, wherein the coil accommodating groove is formed to be recessed from one surface of the shielding layer to have a depth equal to or greater than a wire diameter of the conductive member.

4. The magnetic field shielding module for the electric vehicle of claim 1, wherein the magnetic field shielding module further comprises:
an auxiliary blocking member made of a magnetic material and disposed in the coil accommodating groove,
wherein the auxiliary blocking member comprises:
a plate-shaped support plate,
a partition member extending from the support plate to a predetermined height and formed in a spiral shape, and
a seating groove formed by the support plate and the partition member, and
wherein the partition member is disposed to be positioned between turns adjacent to each other in the planar coil.

5. The magnetic field shielding module for the electric vehicle of claim 1, wherein the coil accommodating groove is formed as an accommodating groove having both sides thereof sealed.

6. A wireless power transfer module for an electric vehicle, comprising:
a wireless power transfer antenna formed of a planar coil in which a conductive member is wound multiple times; and
a magnetic field shielding module made of a magnetic material to shield a magnetic field generated from the planar coil,
wherein the magnetic field shielding module comprises:
a shielding layer including a plurality of unit blocks made of a ferrite material; and
a coil accommodating groove formed to be recessed at a predetermined depth from one surface of the shielding layer to receive the thickness of the planar coil, wherein the shielding layer is formed in a plate shape having a predetermined area by the plurality of unit blocks arranged adjacent to each other,
wherein at least some unit blocks among the plurality of unit blocks include a unit accommodating groove for receiving a part of the planar coil, and
wherein the unit accommodating grooves formed in each of the at least some of the unit blocks are connected to each other in a state in which the plurality of unit blocks are arranged to be adjacent to each other to form the coil accommodating groove having a shape corresponding to the planar coil.

7. The wireless power transfer module for the electric vehicle of claim 6, wherein the plurality of unit blocks comprise:
a first unit block having a curved unit accommodating groove,
a second unit block having a straight unit accommodating groove, and
a third unit block having no unit accommodating groove.

8. The wireless power transfer module for the electric vehicle of claim 6, wherein the coil accommodating groove is formed to be recessed from one surface of the main shielding layer to have a depth equal to a wire diameter of the conductive member, or is formed to be recessed from one surface of the main shielding layer to have a depth greater than a wire diameter of the conductive member.

9. The wireless power transfer module for the electric vehicle of claim 6, wherein the magnetic field shielding module further comprises:
an auxiliary blocking member made of a magnetic material and disposed in the coil accommodating groove,
wherein the auxiliary blocking member comprises:
a plate-shaped support plate,
a partition member extending from the support plate to a predetermined height and formed in a spiral shape, and
a seating groove defined by the support plate and the partition member, wherein the partition member is disposed to be positioned between turns adjacent to each other in the planar coil.

10. The wireless power transfer module for the electric vehicle of claim 6, wherein the coil accommodating groove is formed as an accommodating groove having both sides thereof sealed.
